(19) United States
(12) Patent Application Publication
(10) Pub. No.: US 2003/0232518 A1
(43) Pub. Date: Dec. 18, 2003

(54) Contact mechanism

(75) Inventor: Takaki Tsutsui, Tokyo (JP)

Correspondence Address: Darby & Darby, P.C., 805 Third Avenue, New York, NY, 10022, US

(73) Assignee: Mitsumi Electric Co., Ltd.

(21) Appl. No.: 10/310,104

(22) Filed: Dec. 4, 2002

(30) Foreign Application Priority Data
Jun. 18, 2002 (JP) 2002-177463

(51) Int. Cl. H05K 1/00

(52) U.S. Cl. 439/67

(57) ABSTRACT

The present invention provides a contact mechanism which comprises a fixed contact and a movable contact. The fixed contact is formed by arranging two terminals having a plurality of parallel contacts so that the contacts are disposed in an alternating manner and at a predetermined pattern pitch. The movable contact is disposed above the contacts of the fixed contact to be able to connect with the contacts of the fixed contact. The pattern pitch of the contacts is set within a range of 0.4 mm to 0.8 mm. The present invention provides a durable contact mechanism having stable output levels.

### FIELD OF THE INVENTION

The present invention relates to a contact mechanism used in game devices and the like in which a fixed contact is arranged on a substrate having a predetermined pattern pitch. The contact mechanism is durable, and the output from the contact mechanism is stable.

### BACKGROUND OF THE INVENTION

A conventional contact mechanism is shown in FIGS. 4(a), 4(b), 5(a), and 5(b). FIG. 4(a) shows a fixed contact 1 of a contact mechanism 14. The fixed contact 1 is formed from an approximately E-shaped terminal 2 equipped with a plurality of parallel contacts 2a and an approximately reverse E-shaped terminal 3 equipped with a plurality of parallel contacts 3a. Terminals 2, 3 are arranged on a substrate 4 so that each of contacts 2a are formed adjacent to and alternate with each of contacts 3a. The alternating contacts 2a, 3a have a predetermined pattern pitch.

Terminal 2 is formed in an approximate “E” shape with a copper foil pattern 5 on the substrate 4. Carbon 6 is applied to cover the copper foil pattern 5 in the approximately E-shaped pattern. Terminal 3 is formed in an approximate reversed “E” shape with a copper foil pattern 7 on the substrate 4. Carbon 8 is applied to cover the copper foil pattern 7 in the approximately reversed E-shaped pattern.

Contacts 2a, 3a are disposed in an alternating manner and are arranged with a pattern pitch of approximately 0.8 mm. The width of each of contacts 2a, 3a is approximately 0.8 mm, and the distance separating adjacent contacts 2a, 3a is approximately 0.8 mm.

A movable contact 10 is formed from a pressure-sensitive element 9 which is adhered to the fixed contact 1 using an adhesive 11. The adhesive 11 is applied in a predetermined pattern as shown in FIG. 4(b).

The pattern of the adhesive 11 results in the formation of spaces 12 where the adhesive 11 is not applied at predetermined positions between the movable contact 10 and the alternating contacts 2a, 3a of the fixed contact 1. The spaces 12 separate the alternating contacts 2a, 3a of the fixed contact 1 from the movable contact 10 to allow contact. Thus, the adhesive 11 serves as a spacer.

A rubber piece 13 is disposed above the movable contact 10 so that it can contact and move away from the movable contact 10. The rubber piece 13, the movable contact 10, and the fixed contact 1 form the contact mechanism 14.

The bottom end of the rubber piece 13 of the contact mechanism 14 pushes down on the pressure-sensitive element 9 of the movable contact 10 above the space 12 when the rubber piece 13 is pressed downward. The pressure-sensitive element 9 contacts the fixed contact 1 and generates an output. The downward force on the pressure-sensitive element 9 and the output level from the contact mechanism 14 increase as the rubber piece 13 is pushed down.

FIG. 5(a) is a graph illustrating the relationship between the level of the output and the downward force on the rubber piece 13 after 2 million operations of the contact mechanism 14. The graph shows measurements from a sampling of 18 contact mechanisms. The results indicate that the relationship between the output level and the downward force varies after 2 million applications. The output level is unstable, and the error in the output level increases slightly with each sample.

FIG. 5(b) is a graph illustrating the relationship between the level of the output and the downward force on the rubber piece 13 after 10 million operations of the contact mechanism 14. The relationship between the output level and the downward force is considerably less stable than the relationship shown in FIG. 5(a). The output is extremely unstable and the output error is higher for each sample as the number of applications increases.

The results in FIGS. 5(a) and 5(b) indicate that the output from the contact mechanism 14 will vary even when the usage count is low, and the output level varies depending on the individual sample. Furthermore, the stability of the output level is severely degraded, and the contact mechanism shows inferior durability as the usage count increases. The variation of the overall output level and between the output levels of each sample are high.

A possible cause for error is the wide spacing of the pattern pitch of the contacts 2a, 3a of the fixed contact 1. The contact position between the movable contact 10 and the contacts 2a, 3a of the fixed contact 1 is misaligned, and this misalignment leads to instability and errors in the output levels. Another possible cause for error is the repeated use of the contact mechanism 14. The substrate 4 under repeated use becomes damaged near the ends of the copper foil patterns 5, 7 since the ends of the copper foil patterns 5, 7 are pressed against the carbons 6, 8. The repeated use of the contact mechanism 14 increases the error in the output levels.

### OBJECTS AND SUMMARY OF THE INVENTION

The present invention provides a durable contact mechanism having stable output levels. The contact mechanism comprises a fixed contact and a movable contact. The fixed contact is formed by arranging two terminals having a plurality of parallel contacts so that the contacts are disposed in an alternating manner and at a predetermined pattern pitch. The movable contact is disposed above the contacts of the fixed contact to be able to connect with the contacts of the fixed contact. The pattern pitch of the contacts is set within a range of 0.4 mm-0.8 mm. The contacts of the fixed contact can be made of carbon formed on the substrate. The contacts of the fixed contact can be formed from carbon covering a copper foil pattern formed on the substrate. Furthermore, the movable contact can be a pressure-sensitive element.

The objects, features, and advantages of the present invention will become apparent from the following description read in conjunction with the accompanying drawings in which like reference numerals designate the same elements.

### BRIEF DESCRIPTION OF THE DRAWINGS

FIG. 1(a) is a plan drawing of a fixed contact formed on a substrate according to the present invention.

FIG. 1(b) is a partially cut-away front-view drawing of a contact mechanism according to the present invention.

FIG. 2(a) is a graph illustrating the relationship between downward force and output level for a fixed contact of FIG. 1 after three million operations.

FIG. 2(b) is a graph illustrating the relationship between downward force and output level for a fixed contact of FIG. 1 after ten million operations.

FIG. 3 is a plan drawing of a fixed contact formed on a substrate according to an embodiment of the present invention.

FIG. 4(a) is a plan drawing of a fixed contact formed on a substrate of a conventional contact mechanism.

FIG. 4(b) is a partially cut-away front-view drawing of a conventional contact mechanism.

FIG. 5(a) is a graph showing the relationship between downward force and output level for a fixed contact of FIG. 4 after two million operations.

FIG. 5(b) is a graph showing the relationship between downward force and output level for a fixed contact of FIG. 4 after ten million operations.

### LIST OF DESIGNATORS

1, 21, 35: fixed contact

2, 3, 22, 23, 36, 40: terminal

2a, 3a, 22a, 23a, 36a, 40a: contact

4, 24, 37: substrate

5, 7, 38, 41: copper foil pattern

6, 8, 26, 28, 39, 42: carbon

9, 29: pressure-sensitive element

10, 30: movable contact

11, 31: adhesive

12, 32: space

13, 33: rubber piece

14, 34: contact mechanism

25, 27: connecting section

### DETAILED DESCRIPTION OF THE PREFERRED EMBODIMENTS

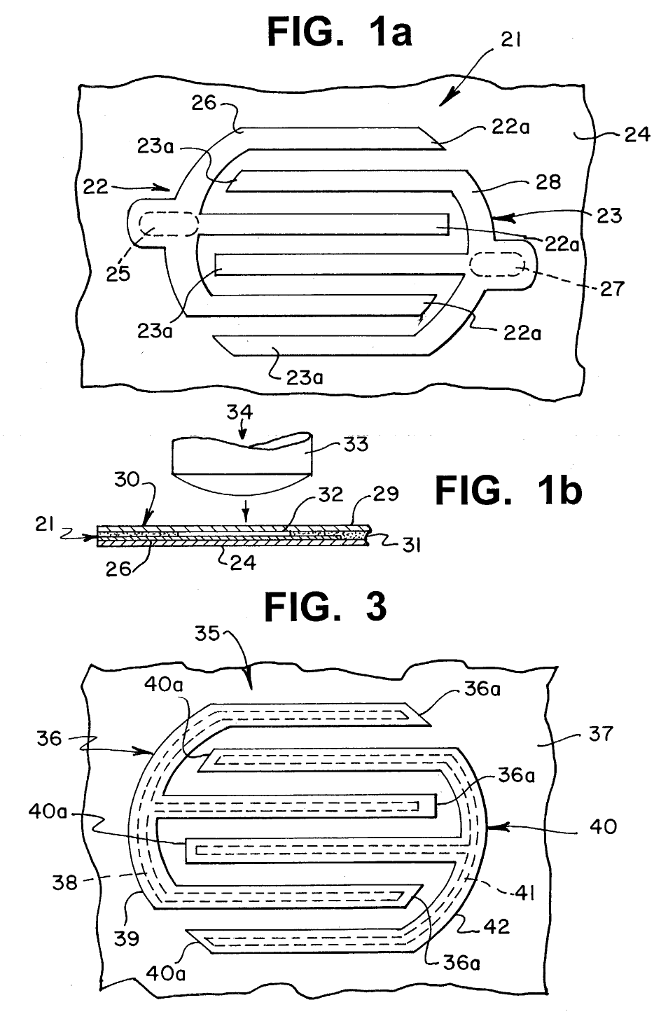

A fixed contact 21 of a contact mechanism 34 is formed from an approximately E-shaped terminal 22 and an approximately reverse E-shaped terminal 23 as shown in FIG. 1(a). Terminal 22 is equipped with a plurality of parallel contacts 22a, and terminal 23 is equipped with a plurality of parallel contacts 23a. Terminals 22, 23 are disposed on the substrate 24 so that the contacts 22a, 23a are arranged in an alternating manner at a predetermined pattern pitch.

A connecting section 25 made of copper foil is disposed in terminal 22 on the substrate 24. Carbon 26 is applied in an approximately E-shaped pattern onto the connecting section 25 and the substrate 24. A connecting section 27 made of copper foil is formed in terminal 23 on the substrate 24. Carbon 28 is applied in an approximately reverse E-shaped pattern on the connecting section 27 and the substrate 24.

The optimal pattern pitch for the alternating contacts 22a, 23a is 0.5 mm. However, the pitch can be within the range of 0.4 mm to 0.8 mm. The width of each of the contacts 22a, 23a is approximately 0.5 mm, and the distance separating adjacent contacts 22a, 23a is approximately 0.5 mm.

The movable contact 30 includes the pressure-sensitive element 29 and is adhered to the fixed contact 21 by an adhesive 31 as shown in FIG. 1(b). The adhesive 31 is applied in a predetermined pattern.

The pattern of the adhesive 31 results in the formation of spaces 32 where the adhesive 31 is not applied at predetermined positions between the movable contact 30 and the contacts 22a, 23a of the fixed contact 21. The spaces 32 separate the contacts 22a, 23a of the fixed contact 21 from the movable contact 30 to allow contact. Thus, the adhesive 31 serves as a spacer.

A rubber piece 33 is disposed above the movable contact 30 so that it can contact and move away from the movable contact 30. The rubber piece 33, the movable contact 30, and the fixed contact 21 form the contact mechanism 34.

The bottom end of the rubber piece 33 pushes down on the pressure-sensitive element 29 above the space 32 when the rubber piece 33 is pressed downward. The pressure-sensitive element 29 contacts the carbon 26, 28 of the contacts 22a, 23a of the fixed contact 21 and generates an output. The downward force on the pressure-sensitive element 29 and the output level from the contact mechanism 34 increase as the rubber piece 33 is pressed down further.

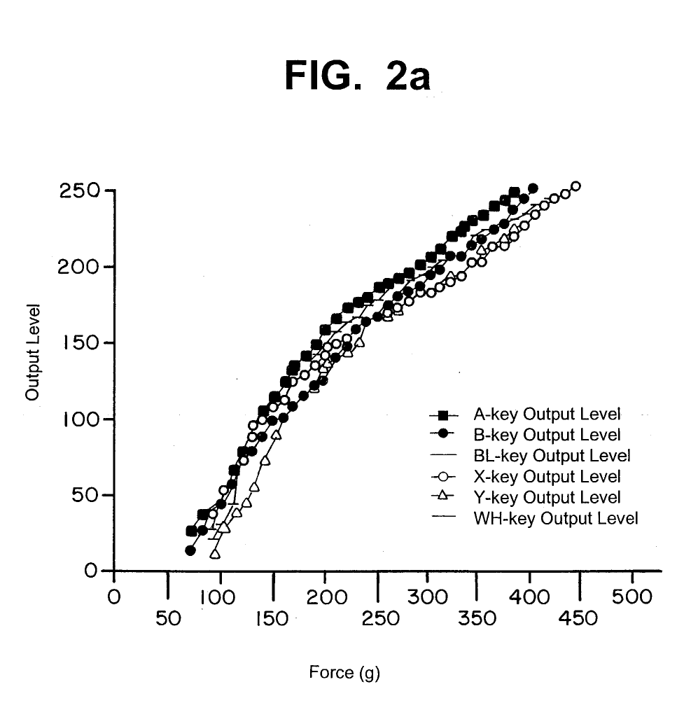

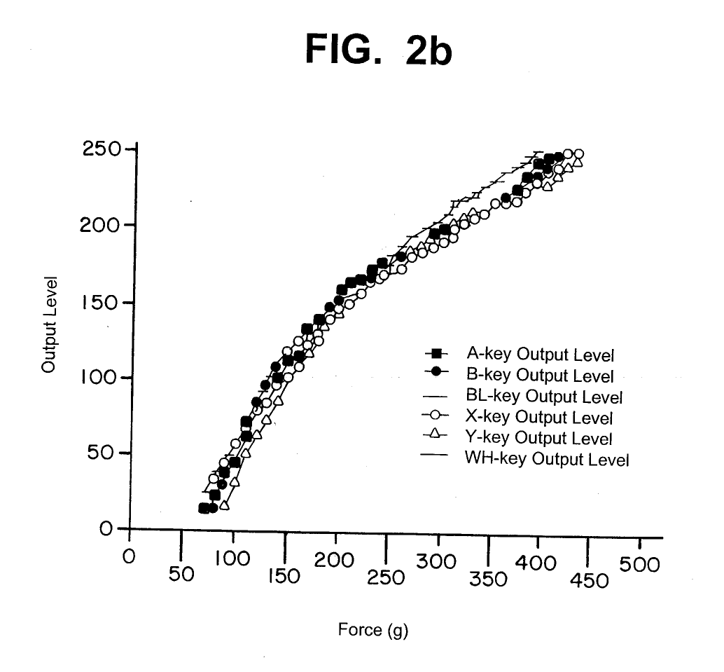

FIG. 2(a) is a graph illustrating the relationship between the output level and the downward force on the rubber piece 33 after approximately 3 million operations. The graph shows measurements from a sampling of six contact mechanisms. The ratio of the output level to the downward force shows negligible variation and negligible output error in the results for the individual samples.

FIG. 2(b) is a graph illustrating the relationship between the output level and the downward force on the rubber piece 33 after approximately 10 million operations. The graph shows measurements from a sampling of six contact mechanisms. The ratio of output level to the downward force shows negligible variation and negligible output error in the results for the individual samples, which is similar to FIG. 2(a).

The results shown in FIGS. 2(a) and 2(b) show that the contact mechanism 14 can provide stable output levels after a large number of operations. There is almost no variation in the output levels when comparing output levels in the individual samples. Therefore, the contact mechanism 14 provides reliable output levels and is durable.

The movable contact 30 in the contact mechanism 34 can include the pressure-sensitive element 29, but it is possible to use other types of contacts in the movable contact 30.

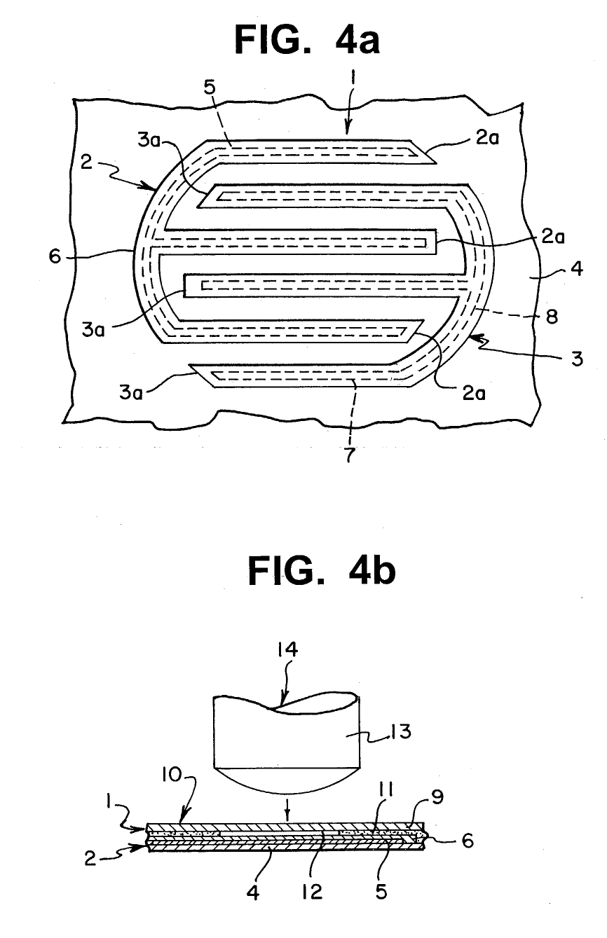

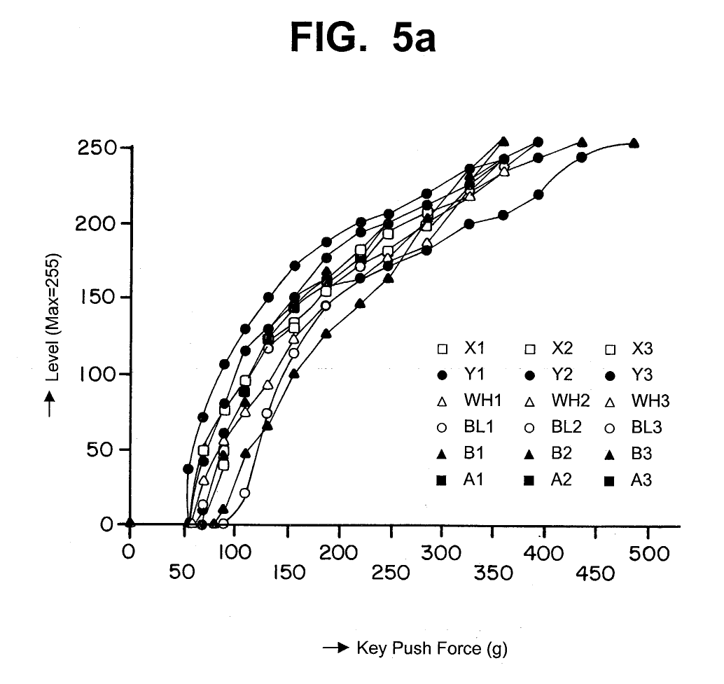

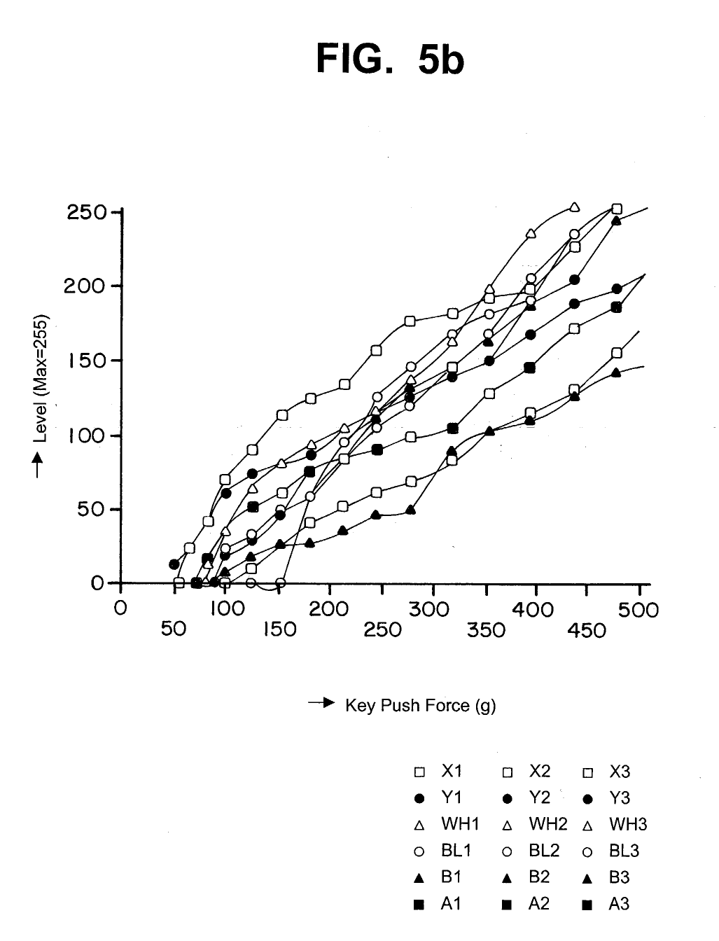

FIG. 3 shows a fixed contact 35 according to an embodiment of the present invention. Fixed contact 35 has a structure that is approximately similar to the conventional fixed contact 1 shown in FIG. 4(a). However, the pattern pitch of the fixed contact 35 is changed to 0.5 mm from the 0.8 mm pattern pitch of the conventional fixed contact 1.

A terminal 36 is formed as a copper foil pattern 38 having an approximately E-shaped pattern disposed on a substrate 37. Carbon 39 is applied in an approximately E-shaped pattern onto copper foil pattern 38 to cover copper foil pattern 38. A terminal 40 is formed as a copper foil pattern 41 having an approximately reverse E-shaped pattern disposed on the substrate 37. Carbon 42 is applied in an approximately reverse E-shaped pattern onto copper foil pattern 41 to cover copper foil pattern 41. Contacts 36a of terminal 36 formed by copper foil pattern 38 and carbon 39 and contacts 40a of terminal 40 formed by copper foil pattern 41 and carbon 42 are arranged adjacent to each other in an alternating manner, and the pattern pitch of the alternating contacts 36a, 40a is 0.5 mm.

The contact mechanism that includes the fixed contact 35 has a narrower pattern pitch. Therefore, the possibility of misalignment of the contact position is reduced and the relationship between the downward force on the rubber piece and the output level of the contact mechanism is stable.

However, the copper foil patterns 38, 41 can damage the carbons 39, 42 after repeated operation of the contact mechanism using fixed contact 35. Therefore, the contact mechanism that uses fixed contact 35 is not sufficiently durable.

An optimal pattern pitch for the contacts 36a, 40a is 0.5 mm. However, the pattern pitch for the contacts 36a, 40a may range from 0.4 mm to 0.8 mm.

The contact mechanism comprises a fixed contact and a movable contact. The fixed contact is formed by arranging two terminals having a plurality of parallel contacts so that the contacts are disposed in an alternating manner and at a predetermined pattern pitch. The movable contact is disposed above the contacts of the fixed contact to be able to connect with the contacts of the fixed contact. The pattern pitch of the contacts is set within a range of 0.4 mm-0.8 mm. Therefore, the contact position can align correctly and the output level is stable.

The contacts of the fixed contact in the contact mechanism can be made of carbon formed on the substrate. The copper foil patterns used in conventional contact mechanisms are not used in the contacts. Therefore, damage to the carbon is reduced, the output level is stable, and the contact mechanism is durable.

The contacts of the fixed contact can be formed from carbon covering a copper foil pattern formed on the substrate. Therefore, the contact position can align correctly and the output level is stable.

Furthermore, the movable contact can be a pressure-sensitive element. Incorporating a pressure-sensitive element provides the additional advantage of the ability to vary the output level according to the amount of downward force applied to the contact mechanism.

Having described the preferred embodiments of the invention with reference to the accompanying drawings, it is to be understood that the invention is not limited to those precise embodiments, and that various changes and modifications may be effected therein by one skilled in the art without departing from the scope or spirit of the invention as defined in the appended claims.

What is claimed is:

1. A contact mechanism comprising:
a fixed contact member on a substrate, said fixed contact member comprising two terminals each comprising a plurality of parallel contacts disposed in an alternating manner and at a predetermined pattern pitch ranging from 0.4 mm to 0.8 mm; and
a movable contact member connectably disposed above said contacts of said fixed contact.

2. A contact mechanism as described in claim 1, wherein said contacts of said fixed contact member comprise carbon formed on said substrate.

3. A contact mechanism as described in claim 1, wherein said contacts of said fixed contact member comprise carbon covering a copper foil pattern formed on said substrate.

4. A contact mechanism as described in claim 1, wherein said movable contact member comprise a pressure-sensitive element.

5. A contact mechanism as described in claim 2, wherein said movable contact member comprise a pressure-sensitive element.

6. A contact mechanism as described in claim 3, wherein said movable contact member comprise a pressure-sensitive element.
